(19) United States
(12) Patent Application Publication
(10) Pub. No.: US 2026/0328833 A1
(43) Pub. Date: Oct. 22, 2026

(54) SEMICONDUCTOR WAFER DEFECT INSPECTION DEVICE AND DEFECT INSPECTION METHOD

(71) Applicant: MIR Tech Inc., Gyeonggi-do (KR)

(72) Inventor: Jeong Ok PARK, Gyeonggi-do (KR)

(73) Assignee: MIR Tech Inc., Gyeonggi-do (KR)

(21) Appl. No.: 19/105,805

(22) PCT Filed: Nov. 29, 2022
(86) PCT No.: PCT/KR2022/019094

§ 371 Date: Feb. 22, 2025

(30) Foreign Application Priority Data
Aug. 22, 2022 (KR) 10-2022-0104751

(51) Int. Cl. G01R 31/28; G01N 21/88; G01N 21/95

(52) U.S. Cl. CPC G01R 31/28; G01N 21/8806; G01N 21/9501

(57) ABSTRACT

Disclosed herein may be a semiconductor wafer defect inspection device and method. The device may include: an inspection module with a camera for capturing an image of a wafer; sensor A and sensor B provided to detect the wafer; a frame trigger configured to generate a trigger signal when at least one of sensors A and B detects the wafer; a frame grabber configured to generate a camera capture start signal when the frame trigger generates a trigger signal, generate a camera capture stop signal when no trigger signal is input; and a management computer configured to detect a defect from the wafer by generating a wafer image using the digital signal, displaying the wafer image on a monitor, and comparing the wafer image with a reference normal image or comparing die images in the wafer image.

### TECHNICAL FIELD

The present disclosure relates to a semiconductor wafer defect inspection device and defect inspection method and, more particularly, to a semiconductor wafer defect inspection device which can be additionally applied to a wafer production line, thereby enabling full inspection of wafers without affecting wafer productivity.

### BACKGROUND ART

Generally, semiconductor chips are manufactured through eight major processes, including a wafer manufacturing process, an oxidation process, a photolithography process, an etching process, a deposition and ion implantation process, a metal wiring process, an electrical die sorting (EDS) process, and a packaging process. To form multiple circuit layers, processes such as the photolithography process, the etching process, and the deposition and ion implantation process are repeated as needed.

During each processing process, various defects such as organic contaminants, metal impurities, scratches, cracks, chipping, and breakage may occur on a wafer surface. After each process is completed, defect inspection is performed, and if preset criteria are satisfied, the wafer proceeds to a subsequent process. Otherwise, the wafer may be reprocessed or discarded.

Furthermore, by determining whether a defect has occurred and identifying the type of the defect, issues with processing equipment used in a latest performed preceding process are identified and promptly addressed, thereby preventing continuous defect occurrence and resulting losses.

In conventional arts, wafer defect inspection is performed, for example, using macro inspection devices that rely on visual observation of inspectors, or in-line automatic optical devices utilizing optical lenses and charged coupled device (CCD) cameras.

However, according to conventional wafer defect inspection devices and methods, not only is inspection accuracy reduced, but inspection time is also increased, making full inspection impossible. Therefore, only sampling inspection (with a 5% inspection rate) can be conducted, thus leading to unnecessary processes being performed on wafers with defects, and making it difficult to promptly identify issues with the processing equipment. As a result, wafer yield decreases, and inability to promptly cope with process incidents causes enormous cost losses.

In addition, because the conventional wafer defect inspection devices are configured as independent devices separate from wafer processing equipment, it is difficult to install the wafer defect inspection devices as additions to the existing wafer processing equipment without modification of the wafer processing equipment. Therefore, it is necessary to install a wafer defect inspection device independently at a location separate from a mass production line and to conduct a defect inspection process separately from a processing process. As a result, wafer defect inspection cannot be performed in real time before and after the processing process.

### RELATED DOCUMENT

(Patent Document 1) Korean Patent Unexamined Publication No. 10-2009-0033977 (Publication date: Apr. 7, 2009)

### DISCLOSURE

### Technical Problem

To overcome the aforementioned problems, the present disclosure is directed to a semiconductor wafer defect inspection device, which can be easily added to a mass production line without modifying the existing mass production line, and which enables real-time full inspection when a wafer is input into and output from a processing process, and a defect inspection method.

### Technical Solution

A semiconductor wafer defect inspection device according to an embodiment of the present disclosure may include: an inspection module provided with a camera for capturing an image of a wafer, and installed in a wafer transfer room of semiconductor processing equipment; sensor A and sensor B installed spaced apart from each other on a linear path identical to a transfer direction of the wafer, and configured to detect the wafer; a frame trigger configured to generate a trigger signal when at least one of sensor A and sensor B detects the wafer (generates an on-signal); a frame grabber configured to generate a camera capture start signal when the frame trigger generates a trigger signal, generate a camera capture stop signal when no trigger signal is input, and convert an analog signal of the image captured by the camera into a digital signal; and a management computer configured to detect a defect from the wafer by generating a wafer image using the digital signal acquired from the frame grabber, displaying the generated wafer image on a connected monitor, and comparing the generated wafer image with a prepared reference normal image or comparing die images in the wafer image with each other.

A semiconductor wafer defect inspection method according to an embodiment of the present disclosure may include: an inspection mode setting operation S10 of setting an operating mode of a frame trigger through an input interface of a management computer; a wafer image capturing operation S20 of capturing an image of a wafer by a camera in motion according to an inspection mode set in the inspection mode setting operation S10; an image comparison operation S30 of comparing the image captured in the wafer image capturing operation S20 with a reference normal image that is prepared and stored in the management computer, or comparing die images in the captured wafer image with each other; a wafer defect determination operation S40 of determining that a defect has occurred in the wafer W in case that a difference is present between the compared images as a result of the image comparison according to each mode in image comparison operation S30; a processing process (processing device) abnormality determination operation S50 of determining which processing process (processing device) has an abnormality in case that a defect has occurred in each inspection mode in the wafer defect determination operation S40; and an abnormality notification operation S60 of notifying a manager, by the management computer, of a result of the determination in the processing process (processing device) abnormality determination operation S50.

### Advantageous Effects

As described above, in a semiconductor wafer defect inspection device and defect inspection method according to the present disclosure, an inspection module may be easily installed in processing equipment of a mass production line without modification of the processing equipment.

Furthermore, full inspection can be performed in real time when the wafer is input into or output from the processing equipment, and the inspection process does not affect transfer of the wafer or implementation of a processing process.

Accordingly, defects in the wafer or processing equipment may be promptly identified without reducing the productivity of the mass production line.

As a result, wafer yield can increase and it becomes possible to promptly cope with process incidents, thereby leading to improved productivity, and a reduction in unnecessary consumption costs.

### BRIEF DESCRIPTION OF DRAWINGS

FIG. 1 is a schematic configuration diagram illustrating semiconductor processing equipment to which a semiconductor wafer defect inspection device according to the present disclosure is applied.

FIG. 2 is a perspective view illustrating an assembled state of an inspection module and a support structure, which are components of the semiconductor wafer defect inspection device according to the present disclosure.

FIG. 3 is a side view illustrating an installation state of a first embodiment of the inspection module.

FIG. 4 is a side view illustrating an installation state of a second embodiment of the inspection module.

FIG. 5 is a schematic view illustrating a lighting module that is a component of the semiconductor wafer defect inspection device according to the present disclosure.

FIG. 6 is an entire configuration diagram illustrating the semiconductor wafer defect inspection device according to the present disclosure.

FIG. 7 is a diagram for describing installation locations of sensor A and sensor B that are components of the semiconductor wafer defect inspection device according to the present disclosure.

FIG. 8 is a diagram for describing operation modes of sensor A and sensor B.

FIG. 9 is a flowchart of a semiconductor wafer defect inspection method according to the present disclosure.

<Description of the Reference Numerals>

| | |
|---|---|
| 1: Wafer loading room | 2: Wafer transfer room |
| 3: Wafer processing room | 100: FOUP |
| 200: Transfer robot | 210: End effector |
| 300: Inspection module | 310: Upper plate |
| 320: Side plate | 325: Connection bracket |
| 330: Lighting module | 331: LED element |
| 340: Box | 350: Prism |
| 360: Camera | 400: Support structure |
| 410: Upper frame | 420: Leg |
| 430: height adjustment screw | 500: Frame trigger |
| 600: Frame grabber | 700: Management computer |
| 800: Lighting controller | W: Wafer |

### MODE FOR INVENTION

In the present disclosure, the accompanying drawings may be depicted with exaggerated expressions to highlight distinctions from conventional arts, ensure clarity, and facilitate understanding of the technology. The terms described below are defined based on the functions of related elements in the present disclosure, and may vary depending on the intention of users or operators or conventions. Therefore, the definitions of the terms should be interpreted based on the technical content throughout this specification. The embodiments are merely illustrative examples of components proposed in the claims of the present disclosure and should not be construed as limiting the present disclosure. The scope of the present disclosure should be interpreted based on the technical spirit set forth in the overall specification.

Hereinafter, embodiments of the present disclosure will be described in detail with reference to the accompanying drawings.

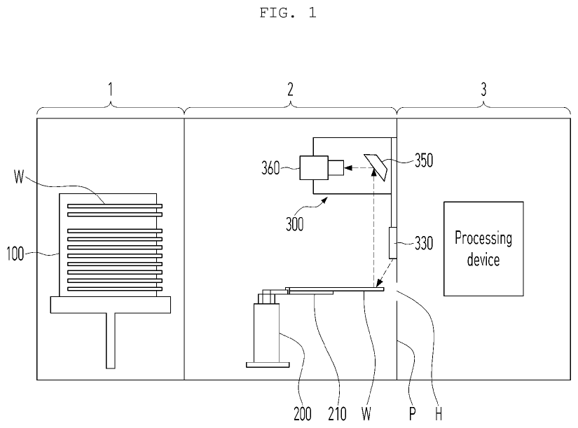

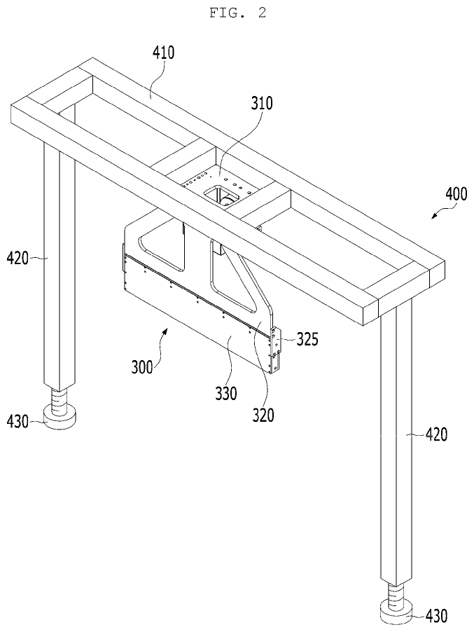

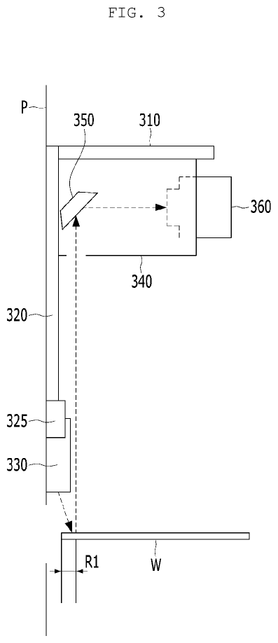

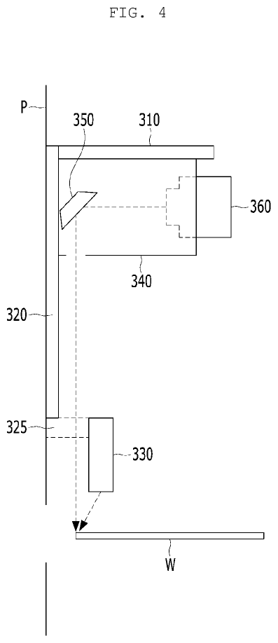

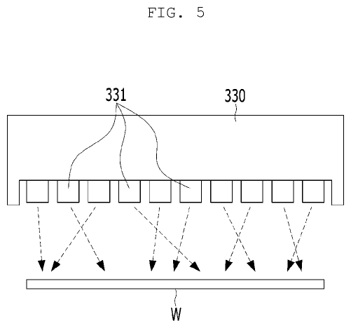

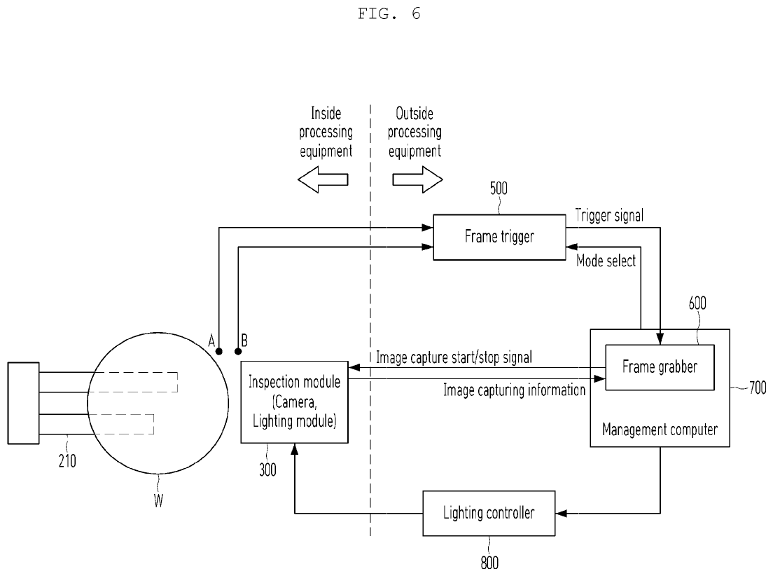

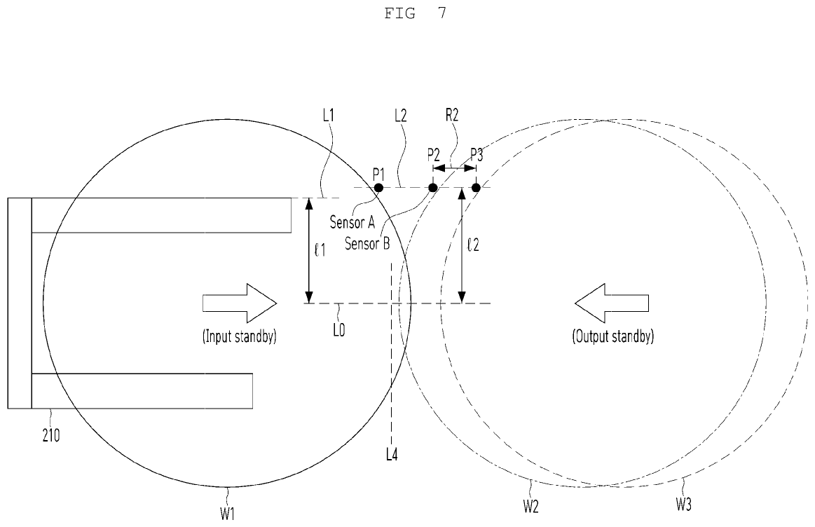

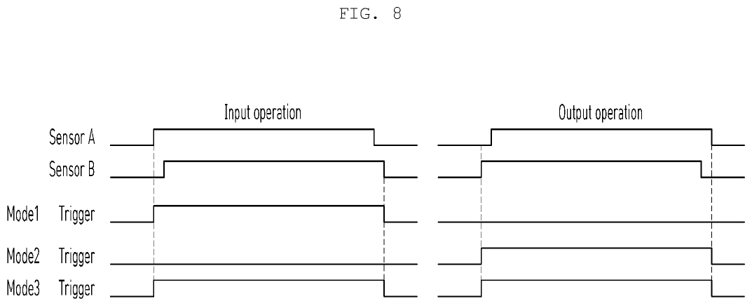

FIG. 1 is a schematic configuration diagram illustrating semiconductor processing equipment to which a semiconductor wafer defect inspection device according to the present disclosure is applied. FIG. 2 is a perspective view illustrating an assembled state of an inspection module and a support structure, which are components of the semiconductor wafer defect inspection device according to the present disclosure. FIG. 3 is a side view illustrating an installation state of a first embodiment of the inspection module. FIG. 4 is a side view illustrating an installation state of a second embodiment of the inspection module. FIG. 5 is a schematic view illustrating a lighting module that is a component of the semiconductor wafer defect inspection device according to the present disclosure. FIG. 6 is an entire configuration diagram illustrating the semiconductor wafer defect inspection device according to the present disclosure. FIG. 7 is a diagram for describing installation locations of sensor A and sensor B that are components of the semiconductor wafer defect inspection device according to the present disclosure. FIG. 8 is a diagram for describing operation modes of sensor A and sensor B.

Referring to FIGS. 1 to 8, the semiconductor wafer defect inspection device according to the present disclosure may include an inspection module 300 provided with a camera 360, sensor A, sensor B, a frame trigger 500, a management computer 700 provided with a frame grabber 600, and a lighting controller 800.

First, the general configuration of processing equipment that performs a semiconductor processing process will be described. As illustrated in FIG. 1, the semiconductor processing equipment may be sectioned into a wafer loading room 1 in which a front opening unified pod (FOUP) 100 loaded with a plurality of wafers W is seated, a wafer transfer room 2 in which a transfer robot 200 is installed to transfer the wafers W, and a wafer processing device room 3 in which processing devices required for wafer processing are installed. Each of the rooms may be sectioned by partition walls P. An opening or hole H may be formed in each of the partition walls P to allow the wafers W to be transferred between the rooms. The opening or hole H may be equipped with an automatic opening/closing unit.

The rooms may be isolated from the outside to protect the wafers W from foreign particles such as dust. Particularly, the wafer processing room 3 in which the processing process is performed may be formed as a sealed vacuum room capable of gas injection and plasma formation.

The transfer robot 200 may typically include one or two articulated arms, and may transfer the wafer W by vacuum suction through an end effector 210 installed on an end of each of the arms. The transfer robot 200 may remove the wafer W from the FOUR 100 and transfer the wafer W to the processing device in the wafer processing room 3, or may reload the wafer W, after the process has been completed by the processing device, into the FOUP 100.

The inspection module 300 may be a mechanism that combines the camera 360 for capturing an image of the wafer W and a lighting module 330 in one place, as shown in FIGS. 1 to 3.

The inspection module 300 may include a horizontal upper plate 310, a trapezoidal side plate 320 that extends vertically downward from one end of the upper plate 310, and a rectangular parallelopiped box 340 that is installed in close contact between the upper plate 310 and the side plate 320.

Furthermore, the inspection module 300 may include the camera 360 that is installed through a front surface of the box 340 (a surface opposite to the side plate 320), the lighting module 330 that is installed on a lower end of the side plate 320 by a connection bracket 325, and a prism 350 that refracts and reflects, at a right angle, light emitted from the lighting module 330 and reflected by the wafer W so that the light is incident on the camera 360.

The lighting module 330 may have an overall rectangular plate shape, with a plurality of light emitting diode (LED) elements 331 arranged in a row on a lower end thereof, and may be positioned on the same vertical surface as the side plate 320.

Light emitted from the lighting module 303 may be reflected by the wafer W, be refracted through the prism 350, and then enter a lens of the camera 360, thereby allowing the camera 360 to capture an image of a surface of the wafer W. A linear through hole may be formed in a lower surface of the box 340 to allow the reflected light from the wafer W to pass through.

As described above, because the prism 350 is used to horizontally refract the light reflected from the wafer W and direct the refracted light into the camera 360, the camera 360 can be installed in a horizontal direction. The foregoing configuration may occupy less space compared to the case where the camera is installed vertically downward, thereby facilitating installation of the inspection module 300 including the camera 360 in the wafer transfer room 2, which is provided as confined space.

As the camera 360, an area scan camera, a line scan camera, a time delay integration (TDI) scan camera may be used; however, this specification provides an example using a TDI scan camera.

The inspection module 300 may be installed in the wafer transfer room 2 at a position in close contact with or as close as possible to the corresponding partition wall P and a ceiling. Due to the aforementioned installation scheme of the inspection module 300, interference between the inspection module 300 and the transfer robot 200 may be reliably prevented, and the maximum operating space of the transfer robot 200 can be secured.

The inspection module 300 may be installed in the wafer transfer room 2 by a support structure 400, as shown in FIG. 2.

The support structure 400 may include an approximately rectangular upper frame 410, and legs 420 that are respectively installed downward on opposite ends of the upper frame 410. A height adjustment screw 430 may be provided on a lower end of each of the legs 420, thus allowing the upper frame 410 to be adjusted in height.

Therefore, by bringing the support structure 400 into close contact with the partition wall P and the ceiling of the wafer transfer room 2 and extending the height adjustment screws 430 (in a direction in which the height adjustment screws exit from the legs), the upper frame 410 may come into pressure contact with the ceiling of the wafer transfer room 2, thereby securing the support structure 400 in place.

The inspection module 300 may be installed on the support structure 400 in a structure where the upper plate 310 is mounted to a lower surface of the upper frame 410. In this way, the inspection module 300 may be securely installed without the need to drill an equipment fastening hole (a bolt hole, a screw hole, or the like) in a wall surface of the wafer transfer room 2. In other words, the inspection module 300 may be installed without making any modifications (or causing damage) to the processing equipment.

Furthermore, although not illustrated, a slider that can move forward, rearward, leftward, and rightward or be secured in position may be installed on the lower surface of the upper frame 410, and the upper frame 410 may be mounted to the slider, thereby making it possible to adjust front-rear and left-right positions of the inspection module 300 relative to the support structure 400.

In some cases, depending on a location of the transfer robot 200 in the wafer transfer room 2 or operational settings of the transfer robot 200, the wafer W may be positioned at a wafer standby location before being transferred to the wafer processing room 3, with an end of the wafer W positioned past a vertical downward position of the prism 350, i.e., a camera image capturing position, as shown in FIG. 3. In this case, since image capturing begins from a portion inside an edge of the wafer W at a start point of the image capturing, an uncaptured region R1 (a region from the edge of the wafer to the image capturing start point) may be present, thus making it impossible to obtain an entire image of the wafer W. Here, the image capturing start position may be adjusted to a leading end of the wafer W by altering only a light irradiation direction of the lighting module 330. However, in this case, another issue may arise where light reflected from the wafer W is blocked by the lighting module 330 and cannot be incident on the prism 350.

To overcome the foregoing problems, the inspection module 300 may be configured as in an embodiment shown in FIG. 4. This embodiment is characterized by positioning the lighting module 330 at a position spaced apart from the side plate 320 toward a trailing end of the wafer W during input of the wafer W (to prevent light blockage caused by the lighting module 330) and directing light emitted by the lighting module 330 toward a point in front of the leading end of the wafer W in a wafer input direction. In this case, the lighting module 330 may be mounted to the side plate 320 via the connection bracket 325 having an appropriate length and installation angle. Since the connection bracket 325 connects facing ends of the side plate 320 and the lighting module 330, the connection bracket 325 does not block light emitted from the lighting module 330 from being incident on the prism 350 after being reflected by the wafer W.

As described above, the image capturing start position can be shifted forward in a travel direction of the wafer W by adjusting the location of the lighting module 330 and changing the light irradiation direction, thereby enabling acquisition of an entire captured image of the wafer W.

FIG. 5 is a schematic view of the lighting module 330. The plurality of LED elements 331 may be installed on the lower end of the light module 330 as a light source. The LED elements 331 may be installed with respective irradiation directions differing from each other. As such, if the irradiation directions of the LED elements 331 differ from each other, light may be incident on the wafer W at various angles, thereby enabling the detection of various defects on the wafer W with a higher probability. Various defects with different shapes, depths, and formation directions may be present on the surface of the wafer W. If light is incident at only a certain angle, some defects may not be easily captured by the camera. However, as in the described embodiment, if light is incident at various angles, a diffuse reflection phenomenon allows various defects to be captured more clearly by the camera 360.

Sensor A and sensor B may be installed on an inner bottom side of the wafer transfer room 2. Sensor A and sensor B may be installed with a certain distance from each other in a linear transfer direction of the wafer W and positioned below the wafer W being transferred, thus enabling detection of the wafer W passing thereabove without interfering with the transfer of the wafer W. In other words, sensor A and sensor B may be turned on when the wafer W is present thereabove, and may be turned off when not present.

As illustrated in FIG. 7, sensor A and sensor B may be installed outside a side edge of the end effector 210, in a plan view, so that sensor A or sensor B can accurately detect only the wafer W without detecting the end effector 210, which holds the wafer W by suction and transfers the wafer W. In other words, a line L2 along which sensors A and B are installed may be positioned further outward from a centerline L0 of the end effector 210 than a side edge line L1 of the end effector 210 ( [symbol] 1< [symbol] 2). That is, since sensors A and B are installed outside a movement path of the end effector 210, sensors A and B may accurately detect whether the wafer W is present above the sensors without sensing the end effector 210.

Furthermore, sensor A may be located at a position P1 outside a circumference of a wafer W1 that is at an input standby location, i.e., ahead of the wafer in the wafer input direction, thereby preventing the wafer W1 in an input standby state from being detected. Similarly, sensor B may also be located at a position P2 to P3 outside a circumference of a wafer W3 that is at an output standby location, i.e., ahead of the wafer in a wafer output direction, thereby preventing the wafer W3 in an output standby state from being detected.

Furthermore, when a trailing end of the wafer is at a position passing an image capture line L4 during the input of the wafer, sensor B is required to be located at the position P2 outside a circumference of a wafer W2 that is at the corresponding position, i.e., behind the wafer input direction. Only when sensor B is at the position P2 can the image of the wafer W be completely captured, ensuring that the trailing end of the wafer W in the travel direction is not truncated. As illustrated in FIG. 7, the issue where the leading end of the wafer W1 located at the input standby location is not captured because an image capture line L4 is positioned inside the leading end of the wafer W1 can be overcome by applying the embodiment described above with reference to FIG. 4.

As described above, sensor B is required to be installed between the position P2 and the position P3 to ensure that the wafer W2, including the trailing end thereof, is completely captured during the wafer input without detecting the wafer W3 that is at the output standby location.

The frame trigger 500 may receive a wafer detection signal from the sensors and generate a trigger signal. Here, if at least one of sensor A and sensor B is in an on-state, a trigger signal may be generated and transmitted to the frame grabber 600.

Because sensor A and sensor B are installed along a linear transfer path of the wafer W, detection signals thereof may be generated with a certain time difference, as illustrated in FIG. 8. In other words, during wafer input, sensor A may be turned on first, followed by sensor B being turned on, and sensor A may be turned off first, followed by sensor B being turned off. On the other hand, during wafer output, sensor B may be turned on first, followed by sensor A being turned on, and sensor B may be turned off first, followed by sensor A being turned off.

The frame trigger 500 may transmit on/off signals of the individual sensors to the management computer 700. The management computer 700 may use the individual sensor on/off signals to display an input or output state of the wafer W on a monitor.

In other words, if on signals are generated in a sequence of sensor A→sensor B, it is determined that the wafer is being input, and a message such as ‘IN’ is displayed on the monitor to indicate the wafer input. Conversely, if on signals are generated in a sequence of sensor B→sensor A, it is determined that the wafer is being output, and a message such as ‘OUT’ is displayed on the monitor to indicate the wafer output. Therefore, a manager may accurately determine the current location of the wafer within the processing equipment based on information displayed on the monitor, and predict a subsequent operation.

The frame grabber 600 may be installed inside the management computer 700 as a high-resolution graphics card used for image processing, and may be an image processing device configured to digitize captured information (analog video signal) from the camera 360 and convert the digitized information into a signal that can be processed by the management computer 700.

Furthermore, the frame grabber 600 may transmit a capture start signal to the camera 360 when a trigger signal is generated (turned on) from the frame trigger 500, and may transmit a capture stop signal to the camera 360 when the trigger signal is turned off.

The management computer 700 may use a digital image signal generated from the frame grabber 600 to display a captured image of the wafer W on the monitor.

Furthermore, the management computer 700 may compare the captured wafer image with a pre-prepared normal wafer image at the corresponding position, or compare die images in the captured wafer image (die-to-die comparison method), to determine whether a defect is present in the image-captured wafer W. When a defect is detected, the management computer 700 may determine a processing device of a process that is responsible for the issue.

Furthermore, the management computer 700 may notify the manager of the process in which the defect has occurred and the type of defect.

The management computer 700 may also determine whether the wafer W can be reprocessed for reuse or needs to be discarded, depending on the extent of the defect in the wafer W.

Furthermore, the management computer 700 can select an operating mode of the frame trigger 500 through an input interface. The operating mode of the frame trigger 500 may include three types: mode 1, mode 2, and mode 3.

As illustrated in FIG. 8, in mode 1, only when the wafer W is input may a trigger signal be generated. That is, in mode 1, when the wafer W is input before the process of the corresponding processing equipment is performed, the image of the wafer W is captured and inspected for defects. Therefore, if a defect is detected in this mode, it can be determined that an issue has occurred in the processing device of the latest performed preceding process.

In mode 2, only when the wafer W is output may a trigger signal be generated. That is, in mode 2, when the wafer W is output after the process of the corresponding processing device is performed, the image of the wafer W is captured and inspected for defects. Therefore, if a defect is detected in this mode, it can be determined that an issue has occurred in the processing device (processing equipment in which the wafer is located) of the currently performed process.

In mode 3, trigger signals may be generated both during the input and output of the wafer W. In this case, the management computer 700 may compare an image captured during the input with an image captured during the output, and use a difference therebetween to determine whether a defect has occurred. Furthermore, by applying the die-to-die method, a wafer defect during the input or a wafer defect during the output may be determined using only the wafer images that are respectively captured during the input and the output (by comparing dies in each captured wafer image).

Therefore, in mode 3, if a defect is detected as a result of comparing the image captured during the input and the image captured during the output, it can be determined that an issue has occurred in the processing device in which the wafer is currently located. Furthermore, when it is determined that a defect is present in the image captured during the input using the die-to-die method, it can be determined that an issue has occurred in the latest performed preceding process (processing device), whereas when it is determined that a defect is present in the image captured during the output, it can be determined that an issue has occurred in the currently performed process (processing device).

The lighting controller 800 may be a device for controlling the operation of the lighting module 330. The lighting controller 800 may keep the lighting module 330 in an always-on state while the processing equipment operates. In addition, the lighting controller 800 may control the amount of current supplied to the lighting module 330 to adjust brightness of the lighting module 330. The manager may appropriately adjust the brightness of the lighting module 330 based on a captured wafer image to increase the resolution of the wafer image, i.e., to obtain a higher-quality wafer image. Specific adjustment commands may be input through a user interface of the management computer 700.

Furthermore, the management computer 700 may instruct the lighting controller 800 to reduce the light intensity of the lighting module 330 according to an embedded program when the processing equipment is in downtime (in which the operation of the transfer robot 200 is also suspended and the operation of transferring the wafer W is not performed). Accordingly, unnecessary power consumption may be minimized.

Hereinafter, a semiconductor wafer defect inspection method using the semiconductor wafer defect inspection device having the above-mentioned configuration will be described.

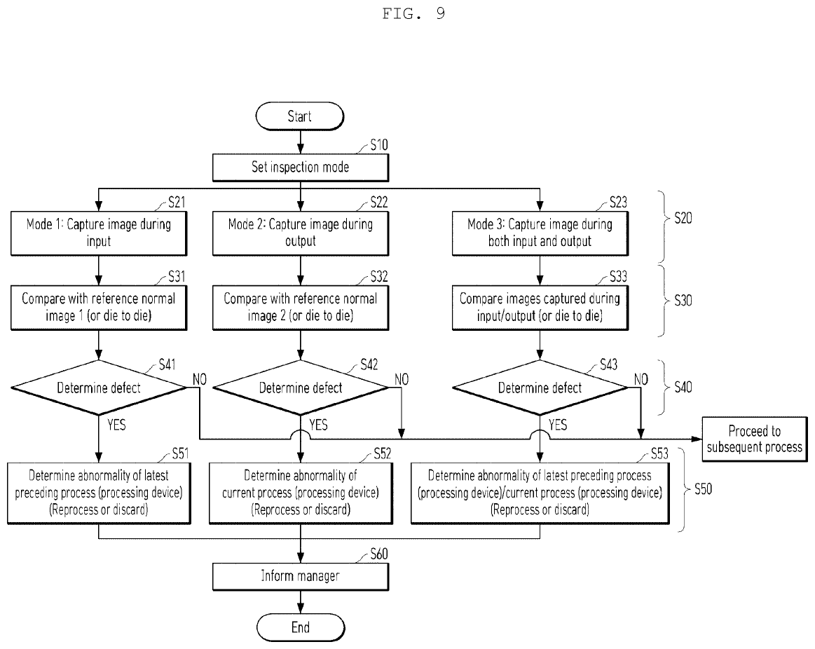

As illustrated in FIG. 9, the semiconductor wafer defect inspection method according to the present disclosure may include an inspection mode setting step S10, a wafer image capturing step S20, an image comparison step S30, a wafer defect determination step S40, a processing process (processing device) abnormality determination step S50, and an abnormality notification step S60 of notifying the manager.

The inspection mode setting step S10 may be the step of setting the operating mode of the frame trigger 500 through the input interface of the management computer 700 by the manager. As described above, the operating mode of the frame trigger 500 may be set to mode 1, mode 2, or mode 3.

The wafer image capturing step S20 may be the step of capturing, by the camera 360, the image of the wafer W being transferred according to the set inspection mode. In other words, in mode 1, a trigger signal may be generated only during wafer input, so that the image of the wafer that is input may be captured (step S21 of capturing the image during the input). In mode 2, a trigger signal may be generated only during wafer output, so that the image of the wafer that is output may be captured (step S22 of capturing the image during the output). In mode 3, trigger signals may be generated both during the input and during the output, both the image of the wafer that is input and the image of the wafer that is output may be captured (step S23 of capturing the image during the input/output).

The image comparison step S30 may be the step of comparing the image captured in the wafer image capturing step S20 with a reference normal image that is prepared in advance and stored in the management computer 700.

The reference normal image may include a plurality of images, such as a reference normal image (reference normal image 1) of the wafer during the input and a reference normal image (reference normal image 2) of the wafer during the output, which may be prepared and stored.

In the case where the current inspection mode is mode 1, step S31 of comparing the image captured during the input with reference normal image 1 may be performed. In the case where the current inspection mode is mode 2, step S32 of comparing the image captured during the output with reference normal image 2 may be performed. In the case where the current inspection mode is mode 3, step S33 of comparing the image captured during the input and the image captured during the output may be performed.

The wafer defect determination step S40 may be the step of determining that a defect has occurred in the wafer W if an image difference is present as a result of the image comparison according to each mode in the preceding image comparison step S30. If a defect is present (YES), the processing process (processing device) abnormality determination step S50 may be performed. If no defect is present (NO), the wafer W may be transferred to a subsequent process.

In all cases of modes 1 to 3 in the image comparison step S30, instead of comparing the captured image with the prepared reference normal image, it is also possible to compare dies in the captured image with each other (die-to-die comparison method), and determine that a defect has occurred when a difference between the compared dies is present, in the wafer defect determination step S40. Each die may be essentially a fundamental unit that substantially forms a single semiconductor chip, and all dies in the wafer W have the same structure (pattern). Therefore, it is possible to determine whether a defect is present by comparing the dies with each other.

The processing process (processing device) abnormality determination step S50 may be the step of determining which process has an issue, i.e., which processing device in a process is abnormal, when a defect has occurred in each inspection mode. If a defect is detected in mode 1, it is determined that the processing device of the latest preceding process is abnormal (in step S51). If a defect is detected in mode 2, it is determined that the processing device of the current process is abnormal (in step S52). If a defect is detected in mode 3, it is also determined that the processing device of the current process is abnormal (in step S53).

Furthermore, in mode 3, if presence of a defect is determined individually for each of the images during the input and during the output using the die-to-die comparison method, it can be determined that the latest preceding process (or the associated processing device) is abnormal when a defect is present in the image during the input, and that the current process (or the associated processing device) is abnormal when a defect is present in the image during the output.

In the processing process (processing device) abnormality determination step S50, it is also possible to determine whether to reprocess the wafer W for further use or discard the wafer W. It is also possible to determine whether to reprocess or discard the wafer W in the preceding wafer defect determination step S40.

As described above, if it is determined which process (or processing device) has an abnormality in the processing process (processing device) abnormality determination step S50, the management computer 700 may perform the abnormality notification step S60 of notifying the manager of the issue. The management computer 700 may notify the manager of the abnormal process (or processing device) by displaying, on the monitor, information indicating which process (processing device) has the issue, notifying the manager through a communication device carried by the manager via wireless communication, or activating an alarm unit (e.g., an alarm lamp, or an alarm speaker) provided in the processing device of the associated process. Therefore, the manager can promptly and accurately recognize which process (or processing device) has an issue, allowing for a more rapid and appropriate response.

Accordingly, it becomes possible to prevent accumulation of defects on the wafer or an increase in the number of defective wafers with defects due to continuation of the processing processes without recognizing the occurrence of an issue.

In the wafer image capturing step S20, a distortion phenomenon may occur in which a captured image of the trailing end of the wafer W in the transfer direction is elongated during both the input and output of the wafer W. The foregoing problem occurs due to a synchronization issue between the transfer speed of the wafer W and an image capturing speed of the camera 360. Typically, during TDI scanning, if a movement speed of a subject is slower than the image capturing speed, a distortion may occur in which the shape of the subject in the captured image appears elongated. If the movement speed of the subject is faster than the image capturing speed, a distortion may occur in which the shape of the subject in the captured image appears shortened.

During the TDI scanning of the wafer, the transfer speed of the transfer robot 200 gradually decreases from a certain distance before a stop position of the wafer and becomes 0 (zero) at the stop position. In other words, when capturing the trailing end of the wafer W in the transfer direction, the transfer speed of the wafer W is markedly reduced compared to before. As a result, synchronization with the image capturing speed of the camera 360 is disrupted, thus causing the trailing-end image of the wafer W to appear elongated.

Therefore, the wafer image capturing step S20 may further include the step in which when a first on-signal occurs, image capturing may be initiated, and when a second on-signal occurs, the image capturing may continue, and when a first off-signal occurs, the image capturing speed of the camera 360 is synchronized with the transfer speed of the wafer, which is decelerated for stopping, by reducing the image capturing speed of the camera 360 according to a program input to the management computer 700 (where the sensor signals are generalized and described as a first signal and a second signal, in which the signal that occurs first is referred to as the first signal, and the signal that occurs later is referred to as the second signal, since sensor A and sensor B are turned on/off in sequence as sensor A and then sensor B during the input, and as sensor B and then sensor A during the output).

Here, a deceleration value of the image capturing speed of the camera 360 may be set to a value that can avoid the distortion phenomenon in which the wafer trailing-end image appears elongated, determined in advance through repeated tests.

As such, since the image capturing speed of the camera is reduced to match the deceleration speed for stopping the wafer during the wafer image capturing process, synchronization between the transfer speed of the wafer and the image capturing speed of the camera may be maintained, thereby preventing the distortion phenomenon in which the wafer trailing-end image appears elongated.

As described above, in a semiconductor wafer defect inspection device and defect inspection method according to the present disclosure, an inspection module may be easily installed in processing equipment of a mass production line without modification of the processing equipment, and real-time full inspection may be performed when a wafer is input or output from the processing equipment. Furthermore, defects of the wafer and processing equipment may be promptly identified without decreasing the productivity of the mass production line. Therefore, as wafer yield increases and it becomes possible to promptly cope with process incidents, the productivity may be enhanced, and unnecessary cost losses may be prevented.

As described above, the present disclosure has been described with reference to the embodiments shown in the drawings, but these are merely exemplary, and it should be understood that various modifications and equivalent other embodiments are possible based on ordinary knowledge in the art. Therefore, the technical scope of the present disclosure is based on the claims to be described below and will have to be determined based on the specific contents of the above-described disclosure.

### INDUSTRIAL APPLICABILITY

The present disclosure relates to a semiconductor wafer defect inspection apparatus and defect inspection method, and can be utilized in industries related to semiconductor wafer production.

1. A semiconductor wafer defect inspection device, comprising:
an inspection module provided with a camera for capturing an image of a wafer, and installed in a wafer transfer room of semiconductor processing equipment;
sensor A and sensor B installed spaced apart from each other on a linear path identical to a transfer direction of the wafer, and configured to detect the wafer;
a frame trigger configured to generate a trigger signal when at least one of sensor A and sensor B detects the wafer (generates an on-signal);
a frame grabber configured to generate a camera capture start signal when the frame trigger generates a trigger signal, generate a camera capture stop signal when no trigger signal is input, and convert an analog signal of the image captured by the camera into a digital signal; and
a management computer configured to detect a defect from the wafer by generating a wafer image using the digital signal acquired from the frame grabber, displaying the generated wafer image on a connected monitor, and comparing the generated wafer image with a prepared reference normal image or comparing die images in the wafer image with each other.

2. The semiconductor wafer defect inspection device according to claim 1, wherein the inspection module comprises a horizontal upper plate, a side plate connected vertically to one end of the upper plate, a box installed between the upper plate and the side plate, and a lighting module installed on a lower end of the side plate, and the camera is installed through one side surface of the box.

3. The semiconductor wafer defect inspection device according to claim 2, wherein the camera is horizontally installed, and a prism is installed inside the box and configured to refract a reflected light from the wafer and direct the refracted light into the camera.

4. The semiconductor wafer defect inspection device according to claim 1,
wherein the inspection module is installed in the wafer transfer room of the processing equipment via a support structure,
wherein the support structure comprises an upper frame, legs respectively installed on opposite ends of the upper frame, and height adjustment screws respectively installed in lower ends of the opposite legs, and
wherein the upper plate of the inspection module is mounted to a lower surface of the upper frame of the support structure.

5. The semiconductor wafer defect inspection device according to claim 4, wherein the support structure and the inspection module are installed in the wafer transfer room without affecting the processing equipment by adjusting extension of the height adjustment screws and bringing the upper frame into pressure contact with a ceiling of the wafer transfer room of the processing equipment.

6. The semiconductor wafer defect inspection device according to claim 2, wherein the lighting module is installed spaced apart forward from the side plate, and irradiates light rearward toward a leading end of the wafer in a wafer input direction.

7. The semiconductor wafer defect inspection device according to claim 2, wherein the lighting module is provided with a plurality of light emitting diode (LED) elements on a lower end thereof, and the LED elements are installed with different irradiation directions to cause diffuse reflection on a surface of the wafer.

8. The semiconductor wafer defect inspection device according to claim 1, wherein sensor A and sensor B are installed outside a movement path of an end effector of the transfer robot.

9. The semiconductor wafer defect inspection device according to claim 8, wherein sensor A is installed outside a circumference of the wafer that is at an input standby location, and positioned ahead of the wafer in a wafer input direction.

10. The semiconductor wafer defect inspection device according to claim 8, wherein sensor B is installed between a position that is both outside a circumference of the wafer that is at an output standby location and is ahead of the wafer in an wafer output direction, and a position that is both outside the circumference of the wafer that is at a location, at which a trailing end of the wafer passes a image capture line of the camera during input of the wafer, and is behind the wafer in the wafer input direction.

11. The semiconductor wafer defect inspection device according to claim 1, wherein when sensor A and sensor B detect the wafer in a sequence of A→B, the management computer displays a message indicating wafer input on the monitor, whereas when sensor A and sensor B detect the wafer in a sequence of B→A, the management computer displays a message indicating wafer output on the monitor.

12. The semiconductor wafer defect inspection device according to claim 1, wherein the frame trigger has an operating mode including mode 1, mode 2, and mode 3, the operating mode being set through an input interface of the management computer, and the frame trigger generates a trigger signal only during wafer input in mode 1, generates a trigger signal only during wafer output in mode 2, and generates trigger signals during both the wafer input and output in mode 3.

13. The semiconductor wafer defect inspection device according to claim 12,
wherein the management computer pre-stores a reference normal image of the wafer in a state before being input to the processing device of the processing equipment and a reference normal image of the wafer in a state after being processed by the processing device and discharged from the processing device,
wherein the management computer detects a defect in mode 1 by comparing a captured image during the wafer input with the corresponding reference normal image, detects a defect in mode 2 by comparing a captured image during the wafer output with the corresponding reference normal image, and detects a defect in mode 3 by comparing the captured image during the wafer input with the captured image during the wafer output, and
wherein the management computer determines that an abnormality is present in a latest performed preceding processing process (or processing device) in case that a defect is detected in mode 1, and determines that an abnormality is present in a currently performed processing process (or processing device) in case that a defect is detected in mode 2 or mode 3.

14. The semiconductor wafer defect inspection device according to claim 12,
wherein the management computer detects a defect in mode 1 by comparing die images in a wafer image captured during the wafer input with each other, detects a defect in mode 2 by comparing die images in a wafer image captured during the wafer output with each other, and detects, in mode 3, a defect from each of the wafer image during the wafer input and the wafer image during the wafer output by performing both comparison of the die images in the wafer image captured during the wafer input and comparison of the die images in the wafer image captured during the wafer output, and
wherein the management computer determines that an abnormality is present in a latest performed preceding processing process (or processing device) in case that a defect is detected in mode 1, determines that an abnormality is present in a currently performed processing process (or processing device) in case that a defect is detected in mode 2, and determines in mode 3 that an abnormality is present in a latest performed preceding processing process (or processing device) in case that a defect is detected from an image captured during the wafer input, and an abnormality is present in a currently performed processing process (or processing device) in case that a defect is detected from an image captured during the wafer output.

15. A semiconductor wafer defect inspection method, comprising:
an inspection mode setting operation S10 of setting an operating mode of a frame trigger through an input interface of a management computer;
a wafer image capturing operation S20 of capturing an image of a wafer by a camera in motion according to an inspection mode set in the inspection mode setting operation S10;
an image comparison operation S30 of comparing the image captured in the wafer image capturing operation S20 with a reference normal image that is prepared and in the management computer, or comparing die images in the captured wafer image with each other;
a wafer defect determination operation S40 of determining that a defect has occurred in the wafer W in case that a difference is present between the compared images as a result of the image comparison according to each mode in image comparison operation S30;
a processing process (processing device) abnormality determination operation S50 of determining which processing process (processing device) has an abnormality in case that a defect has occurred in each inspection mode in the wafer defect determination operation S40; and
an abnormality notification operation S60 of notifying a manager, by the management computer, of a result of the determination in the processing process (processing device) abnormality determination operation S50.

16. The semiconductor wafer defect inspection method according to claim 15,
wherein in the inspection mode setting operation S10, any one of mode 1, mode 2, and mode 3 is set,
wherein in the wafer image capturing operation S20, the image of the wafer is captured in mode 1 only during wafer input (operation S21 of capturing the image during the input), the image of the wafer is captured in mode 2 only during wafer output (operation S22 of capturing the image during the output), and the image of the wafer is captured in mode 3 during both the wafer input and output (operation S23 of capturing the image during the input/output),
wherein in the image comparison operation S30, in case of mode 1, the image captured during the input is compared with a corresponding reference normal image (in operation S31), in case of mode 2, the image captured during the output is compared with a corresponding reference normal image (in operation S32), and in case of mode 3, the image captured during the input and the image captured during the output are compared with each other (in operation S33), and
wherein in the processing process (processing device) abnormality determination operation S50, in case that a defect is detected in mode 1, a processing device of a latest preceding process is determined to have an abnormality (in operation S51), and in case that a defect is detected in mode 2 or mode 3, a processing device of a current process is determined to have an abnormality (in operation S52 or S53).

17. The semiconductor wafer defect inspection method according to claim 15,
wherein in the inspection mode setting operation S10, any one of mode 1, mode 2, and mode 3 is set,
wherein in the wafer image capturing operation S20, the image of the wafer is captured in mode 1 only during wafer input (an operation S21 of capturing the image during the input), the image of the wafer is captured in mode 2 only during wafer output (an operation S22 of capturing the image during the output), and the image of the wafer is captured in mode 3 during both the wafer input and output (an operation S23 of capturing the image during the input/output),
wherein in the image comparison operation S30, in case of mode 1, die images in the image captured during the input are compared with each other (in operation S31), in case of mode 2, die images in the image captured during the output are compared with each other (in operation S32), and in case of mode 3, comparison of die images in the image captured during the input and comparison of die images in the image captured during the output are each performed (in operation S33), and
wherein in the processing process (processing device) abnormality determination operation S50, in case that a defect is detected in mode 1, a processing device of a latest preceding process is determined to have an abnormality (in operation S51), in case that a defect is detected in mode 2, a processing device of a current process is determined to have an abnormality (in operation S52), and in mode 3, in case that a defect is detected from the image captured during the input, a latest performed preceding processing process (processing device) is determined to have an abnormality, and in case that a defect is detected from the image during the output, a currently performed processing process (processing device) is determined to have an abnormality (in operation S53).

18. The semiconductor wafer defect inspection method according to claim 15, wherein the wafer image capturing operation S20 further comprises an operation in which when any one sensor of sensor A and sensor B generates an on-signal, image capturing is initiated, and when a remaining sensor generates an on-signal, the image capturing continues, and when any one sensor of sensors A and B generates an off signal, the management computer decreases an image capturing speed of the camera and synchronizes the image capturing speed of the camera with a transfer speed of the wafer that is decelerated for stopping.
